(19) United States
(12) Patent Application Publication
(10) Pub. No.: US 2018/0146720 A1
(43) Pub. Date: May 31, 2018

(54) ARTICLE OF CLOTHING, METHOD FOR MANUFACTURING A GLOVE, AND GLOVE SET

(71) Applicant: WORKAROUND GMBH, Muenchen (DE)

(72) Inventors: Hans Christian SITTIG, Freiburg (DE); Konstantin BRUNNBAUER, Ruderting (DE); Michael KETTNER, Muenchen (DE)

(21) Appl. No.: 15/825,945

(22) Filed: Nov. 29, 2017

(30) Foreign Application Priority Data
Nov. 30, 2016 (DE) 10 2016 123 093.6

(51) Int. Cl. A41D 1/00; A41D 19/00; A41D 19/04; H03K 17/96

(52) U.S. Cl. CPC A41D 1/002; A41D 19/0024; A41D 2600/20; H03K 17/962; H03K 17/9645; A41D 19/04

(57) ABSTRACT

An article of clothing, in particular an article of work clothing, to be worn on the body has a trigger device. The trigger device comprises an electric trigger which has an actuation side facing away from the body, and a rigid protective element for the trigger, which at least partly laterally surrounds the trigger. In a side view of the trigger device the protective element extends at least up to the actuation side of the trigger facing away from the body in its trigger position.

Furthermore, a method for manufacturing a glove and a glove set are shown.

### FIELD OF THE DISCLOSURE

This present disclosure relates to an article of clothing, in particular an article of work clothing to be worn on the body, with a trigger device, a method for manufacturing a glove and a glove set, in particular a work glove set, with at least two gloves of different size.

### TECHNICAL BACKGROUND

Articles of clothing with an electric trigger are known and are used for example in combination with one or more electronic modules. These electronic modules usually include sensors and can also be attached to the article of clothing, so that a portable sensor system is obtained, a so-called “wearable”.

For example, the electronic module is a barcode scanner and the trigger serves to trigger a scan operation. The trigger can also be used for other purposes, such as the counting of operations or the handling of a machine.

The trigger therefore must be easy to activate on the one hand, but on the other hand must also be protected from inadvertent activation. Easy-to-reach triggers on exposed areas, such as the hand surface or the chest, are easy to reach, but these triggers can easily be actuated wrongly when grasping, pressing or carrying objects.

### BRIEF SUMMARY

It therefore is the object of the present disclosure to provide an article of clothing with a trigger device as well as a glove set, in which the trigger is protected from misactuations, which offer wearing comfort, and which are inexpensive to manufacture.

The object is solved by an article of clothing, in particular an article of work clothing to be worn on the body, with a trigger device, wherein the trigger device comprises an electric trigger which has an actuation side facing away from the body, and a rigid protective element for the trigger which laterally surrounds the trigger at least partly, wherein in a side view of the trigger device the protective element extends at least up to the actuation side of the trigger in its trigger position facing away from the body. The protective element may completely surround the trigger. The protective element also can be made of substantially inelastic plastic material. In particular, the protective element is a component formed separately from a housing for the electronic module which is actuated by the trigger device and/or the protective element is not a housing for the electronic module which is actuated by the trigger device.

The used terms “facing away from the body”, “facing the body” and “laterally” relate to the position of the parts of the article of clothing in proper use of the article of clothing relative to the body of the user. “Sidewards” describes a direction parallel to the body or transversely to an actuating direction of the trigger. The trigger has an actuating direction B, which for example extends substantially vertically to the actuation side facing away from the body and which may be vertical to the body. A side view is understood to be a view parallel to the body surface in the region of the article of clothing or transversely to the actuating direction of the trigger.

It is the idea underlying the present disclosure that the protective element protects the trigger from inadvertent actuations. This is achieved in that, as seen from the body, the protective element extends further than the actuation side of the trigger facing away from the body when the trigger is in its trigger position.

The trigger position is the position of the trigger at the moment in which a signal is generated or a contact is closed during its actuation. In the case of a push button as trigger, the trigger position is the position of a tappet of the push button upon reaching the pressure point of the push button.

Thus, the protective element absorbs all forces which act on the article of clothing in the region of the trigger. In particular, planar forces are absorbed. The trigger can hence be actuated only by a targeted actuation past the protective element. It is thereby prevented that the trigger is activated by mistake when the body part on which the article of clothing is worn hits an object in the usual way.

In case the article of clothing is a glove, the trigger can simply be activated by pressing with a finger. At the same time, the protective element prevents that an erroneous activation occurs for example when carrying objects.

The trigger device can be provided on a textile layer, in particular an outer textile layer of the article of clothing.

In addition, at least one cable can be attached to the trigger itself, which extends through the textile portion of the article of clothing and can be used for electrically contacting the trigger.

The trigger can include a push button and/or a touch-sensitive surface, whereby the trigger can be operated easily and in a known way. What is conceivable therefor is a capacitive and/or resistive touch-sensitive surface.

In the case of a trigger which is designed as touch-sensitive surface, the touch-sensitive surface itself can represent the actuation side facing away from the body.

For example, in the non-actuated starting position the actuation side of the trigger facing away from the body does not protrude beyond the protective element and/or completely lies in the area surrounded by the protective element, whereby the number of erroneous activations can be reduced further.

To increase the wearing comfort of the article of clothing, the trigger device may include a cushioning unit which at least partly surrounds the protective element laterally and/or on its side facing the body. The cushioning unit also can surround the protective element below, i.e. on its side facing the body. The cushioning unit may also surround the protective element laterally and/or on its bottom side only partly. The trigger may also be provided off-center in the cushioning unit.

The cushioning unit may be of plate-like design. For example, it has a rectangular, circular or oval circumference or a circumference in the form of a rectangle with semicircular segments attached on opposite sides.

For example, the cushioning unit includes a padding layer, in particular of a foamed material, and at least one top layer. The top layer for example is fixed to the padding layer and can be provided on the side of the padding layer facing away from the body and/or facing the body. By the at least one top layer the stability of the padding layer is increased. For this purpose, the top layer for example can contain polyurethane (PU) and/or nylon.

In one embodiment of the present disclosure the protective element may include a closed ring-shaped portion, wherein the trigger is arranged within the ring-shaped portion so that the protective element is designed in a simple and effective way.

For example, the protective element includes a bottom which at least for the most part closes the ring-shaped portion on the side facing the body and on which the trigger is mounted. For example, the protective element is trough-shaped. Beside its protective function, the protective element may thereby serve to fix the trigger to the article of clothing at the same time.

To be able to easily operate the trigger, the protective element has an actuating opening on its side facing away from the body. The user can reach into the actuating opening with a finger, in order to actuate the trigger. The actuating opening for example is circular, oval or in the form of a rectangle with semicircular segments attached on opposite sides of the rectangle. For example, the actuating opening is parallel to the body surface.

In one aspect of the present disclosure, the trigger comprises a pressure plate which forms the actuation side facing away from the body, which has the shape of the actuating opening and which is arranged in the actuating opening at least partly, wherein the pressure plate is resiliently mounted with respect to the protective element, in particular integrally molded via webs. The pressure plate can be mounted on the protective element or on the cushioning unit. The pressure plate allows that the trigger is activated over the entire surface of the actuating opening.

The protective element and the trigger and/or the protective element, the trigger and the cushioning unit can be a pre-assembled unit. This unit may then form the trigger device. The manufacturing process is thereby simplified.

In a further aspect of the present disclosure, the article of clothing is a glove, in particular a work glove, with a hand surface portion covering the hand surface, wherein the trigger device is arranged on the hand surface portion, in particular is arranged in the area of the hand surface portion which in proper use of the glove lies between the ball of the thumb and the metacarpophalangeal joints of the middle and ring fingers. In this way, the trigger can be placed in a glove at a point which is easy to reach ergonomically. Despite this exposed position of the trigger on the inner hand surface, the protective element prevents a high number of erroneous activations. Even if the glove is a work glove, which is used during assembly, large forces for inserting components can nevertheless be applied with the inner hand surface of the hand on which the glove is worn, as the trigger is protected by the protective element.

In accordance with this present disclosure, a glove is to be understood not only as a full glove with fingers, but also as a glove at which individual fingers are missing or only attachments for fingers are present, such as a finger-stall, and also a glove which encloses only parts of the hand, such as an overcoat or a bandage.

Another advantage of placing the trigger on the inner hand surface lies in the fact that no functional elements such as cables, buttons or electronic components have to be arranged in the region of the fingers to provide the functionality of the trigger. It is thereby possible to fabricate the glove for example without fingers, so that the user of the glove has the fingers uncovered and/or the user can wear further articles of clothing, in particular a further glove.

For example, the glove includes a holder for an electronic module, wherein the holder has at least one electrical contact element which is electrically connected with the trigger. For example, the holder is arranged on the part of the glove which in proper use of the glove rests against the back of the hand. In this way, a portable sensor or electronic system is produced. The electronic module can comprise a barcode scanner.

To further lower the manufacturing costs, the glove may include a tape-shaped base body in which a cutout for a thumb is formed. The base body for example has no fingers or attachments for fingers, except the cutout for the thumb. The cutout for example can extend almost across the entire width of the base body. Thereby, it is possible that the same base body can be used for manufacturing both gloves for the left hand and gloves for the right hand.

Further, the object is achieved by a method for manufacturing a glove according to the present disclosure, comprising the following steps:
a) providing a tape-shaped base body,
b) placing the trigger device on the side of the base body facing away from the body, and
c) heating and connecting, in particular pressing the base body to the trigger device,

wherein after connecting, in particular pressing, the trigger device protrudes at least partly from the remaining base body on the side facing the body. The “remaining base body” is the part of the base body which upon connecting, in particular pressing, has not been deformed by the trigger device. A glove according to the present disclosure can thereby be manufactured in a cost-efficient way.

Connecting may include adhesive bonding.

For example, the trigger device can be protected from dirt when before connecting, in particular pressing, a cover is arranged on the trigger device, which after connecting, in particular pressing, forms one surface with the remaining base body, which faces away from the body.

For example, before connecting, in particular pressing, a holder for an electronic module is placed on the same side of the base body as the trigger device, wherein after connecting, in particular pressing, the holder is arranged on the side of the base body facing away from the body. In this way, the manufacturing process can be further simplified.

Furthermore, the object is solved by a glove set, in particular a work glove set with at least two gloves of different size, which have a hand surface portion of different size covering the hand surface, and with a trigger device on each glove, wherein the trigger devices for the differently large gloves are of oblong shape, and wherein with increasingly smaller gloves the trigger device with its longitudinal axis is arranged at an increasingly larger angle to the transverse direction of the hand surface portion. It is thereby possible to ergonomically place the trigger device also on differently large hand surfaces.

For example, at least two, in particular all of the trigger devices of the at least two gloves of different size are equally large, in particular identical, whereby the manufacturing costs of gloves of different size can be lowered.

For example, the angle between the longitudinal axis of the trigger device and the transverse direction of the hand surface portion in a large glove, such as size L, is between 0° and 20°, in a medium-size glove, such as size M, between 15° and 35°, and in a small glove, such as size S, between 30° and 50°. In particular, the angles for instance are 10°, 25° and 40°, respectively.

### BRIEF DESCRIPTION OF THE DRAWINGS

Further features and advantages of the present disclosure can be taken from the following description and from the attached drawings to which reference is made. In the drawings:

FIG. 1a shows an article of clothing according to the present disclosure in a top view,

FIG. 1b shows the article of clothing of FIG. 1a in a front view,

FIG. 2 shows a simplified detail section through the article of clothing according to the present disclosure as shown in FIG. 1a along line II-II,

FIG. 3 shows a top view of a trigger device of the article of clothing according to FIG. 1a,

FIGS. 4a and 4b show simplified sectional representations of parts of the trigger device,

FIGS. 5a to 5c show a glove set according to the present disclosure in the donned condition,

FIGS. 6a and 6b show a second embodiment of the article of clothing according to the present disclosure in front and rear views, and

FIG. 6c shows in simplified form the trigger device of the article of clothing according to FIG. 6a in a section.

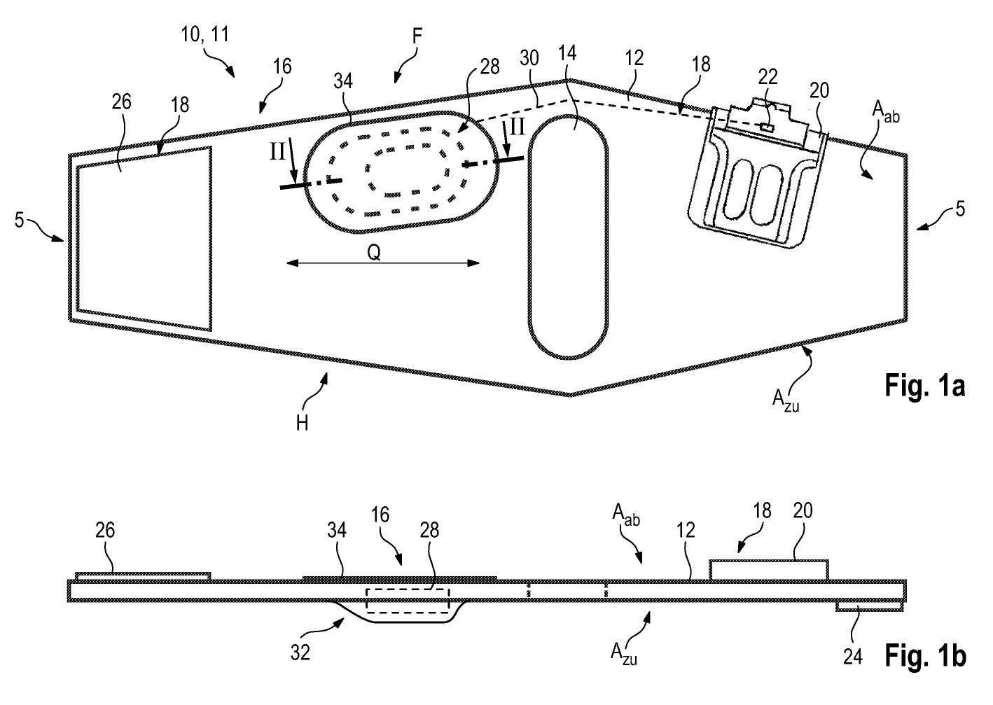

FIGS. 1a and 1b show an article of clothing 10. In the illustrated embodiment, the article of clothing 10 is a glove 11, in particular a work glove. It is also conceivable, however, that the article of clothing 10 is a jacket, a pullover, a pair of trousers or another garment.

The article of clothing 10 or the glove 11 has a tape-shaped base body 12, for example made of a textile layer, for example of an elastic textile.

The tape-shaped base body 12 has thus two short front edges S and two long longitudinal edges, wherein the longitudinal edge which faces the fingers of the user when the article of clothing 10 is properly worn is referred to as finger-side edge F. The opposite longitudinal edge then faces the wrist and is therefore called wrist-side edge H.

The base body 12 likewise has a side A_{ab} facing away from the body and a side A_{zu} facing the body, wherein the side A_{zu} facing the body rests against the body or the further clothing of the user when the article of clothing 10 is worn properly.

In the base body 12 an elongate cutout 14 is provided, which for example has a rectangular shape with attached semicircular segments and which can extend across almost the entire width of the base body, i.e. almost from the wrist-side edge H to the finger-side edge F.

Fingers or attachments for fingers are not provided on the base body 12.

Thus, the glove 11 is no full glove, but resembles an overcoat or a bandage which encloses only parts of the hand and which need not be drawn over the hand, but is closed around the hand.

The base body 12 also has a hand surface portion 16 and a hand back portion 18, which are separated from each other by the cutout 14.

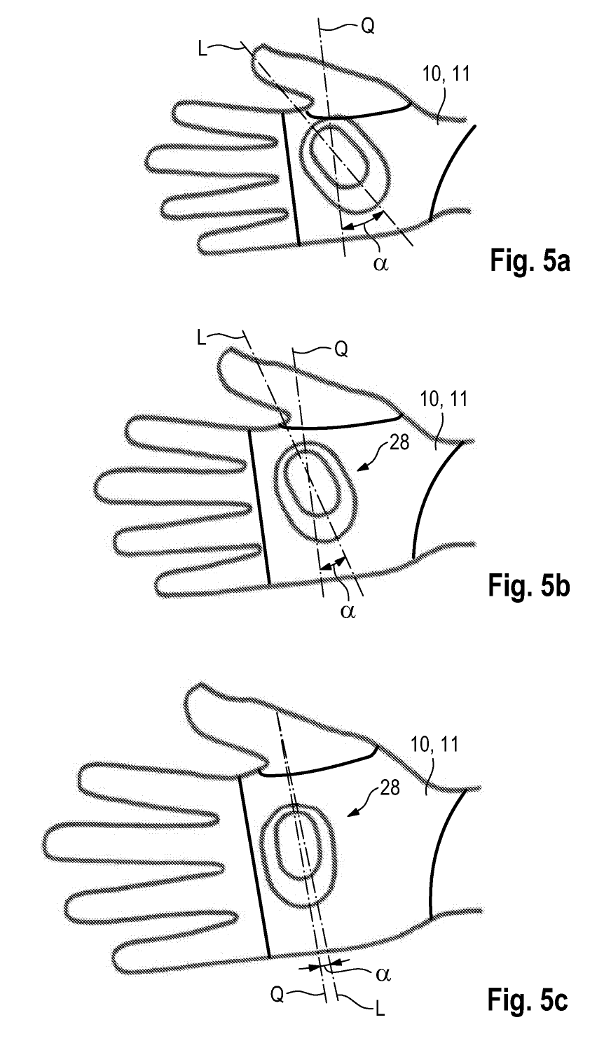

When the article of clothing 10 is worn properly, the hand surface portion 16 is located on the hand surface of the user (cf. FIG. 5) and the hand back portion 18 is located on the back of the hand of the user. The hand surface portion 16 then covers the hand surface of the user for the most part. In FIG. 1 the hand surface portion 16 is on the left and the hand back portions 18 are on the left and right of the hand surface portion 16.

The hand surface portion 16 has a transverse axis Q which with respect to the base body 12 extends for example vertically to the width.

With respect to the hand of the user, the transverse direction Q extends transversely to a longitudinal axis of the middle finger in the fully outstretched condition.

On the hand back portion 18 a holder 20 for an electronic module (not shown) is mounted on the side A_{ab} of the base body 12 facing away from the body. The electronic module for example comprises a barcode scanner.

The holder 20 is provided at the finger-side edge F of the base body 12 and can protrude beyond the finger-side edge F.

On the holder 20 two contact elements 22 also are provided for contacting the electronic module.

In addition, a first fastening element 24 is attached to the right hand back portion 18 on the side A_{zu} of the base body 12 facing the body. The first fastening element 24 for example is located close to the front edge S.

On the left hand back portion 18 a second fastening element 26 is likewise attached to the front edge S, but on the side A_{ab} facing away from the body, which cooperates with the first fastening portion 24 when the article of clothing 10 is worn properly, so that the base body 12 or the entire glove 11 can be fixed to the hand of the user. The first and the second fastening element 24, 26 for example can form a hook-and-loop fastener.

It is of course also conceivable that the first fastening element 24 is provided on the side A_{ab} facing away from the body and the second fastening element 26 is provided on the side A_{zu} facing the body.

It is furthermore conceivable that close to one of the front edges S a cutout or another opening is provided, through which the opposite front edge S and parts of the base body 12 can be pulled through. The part of the base body 12 pulled through the cutout then can be attached to the part of the base body 12 not pulled through, for example by means of a hook-and-loop fastener, in order to fix the glove 11 at the hand of the user.

In addition, a trigger device 28 is arranged in the hand surface portion 16, wherein at least one cable 30, for example a two-core cable, extends from the trigger device 28 to the contact elements 22 of the holder 20. By means of the cable 30 an electrical connection can thus be produced between the contact elements 22 and the trigger device 28.

The trigger device 28 is provided on the side A_{ab} of the base body 12 facing away from the body. However, the base body 12 is deformed in the region of the trigger device 28 such that in this region the trigger device 28 and the base body 12 form an elevation 32 on the side A_{zu} facing the body in the otherwise flat shape of the base body 12. The region of the base body 12 which is not deformed by the trigger device 28 is referred to as remaining base body 12, and the trigger device 28 at least partly protrudes from the remaining base body 12.

One could also say that the trigger device 28 causes a bulge on the side A_{zu} facing the body.

On the side A_{ab} facing away from the body the trigger device 28 is concealed by a cover 34, for example a textile layer. The cover 34 protrudes laterally beyond the trigger device 28 and is connected, for example adhesively bonded, to the base body 12 all around the trigger device 28.

In addition, the cover 34 can contain several cutouts, for example to provide access to the trigger 36.

Thus, the cover 34 closes the depression in the base body 12 caused by the trigger device 28 and approximately forms a planar surface with the side A_{ab} of the remaining base body 12 facing away from the body.

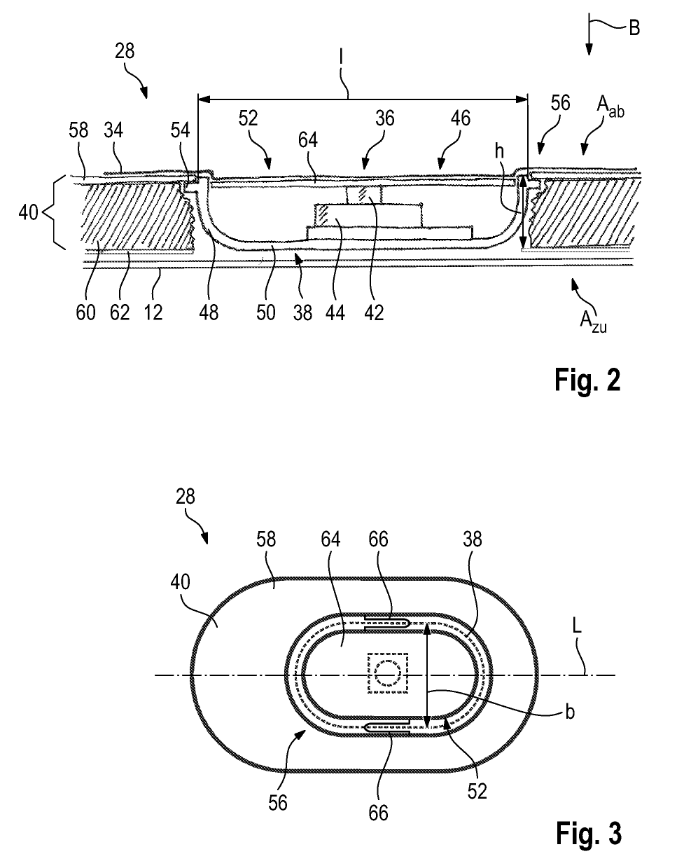

In FIGS. 2 and 3, the trigger device 28 is shown in detail. FIG. 2 shows a side view parallel to the body surface and transversely to the actuating direction B.

The trigger device 28 includes an electric trigger 36, a protective element 38 and a cushioning unit 40 and in a top view has an elongated shape with a longitudinal axis L.

The longitudinal axis L of the trigger device 28 forms an angle α with the transverse direction Q of the hand surface portion 16 (FIG. 5).

The trigger 36 has an actuating direction B and in the illustrated embodiment comprises a push button with a tappet 42, a pedestal 44 and a pressure plate 64 arranged above the tappet 42.

The trigger 36, more exactly the pedestal 44, is connected with the cable 30 and includes a contact (not shown) which can connect the two cores of the cable 30.

The trigger 36 has an actuation side 46 facing away from the body, which in the illustrated exemplary embodiment is formed by the side of the pressure plate 64 facing away from the body. By pressing the pressure plate 64 and shifting the tappet 42 in actuating direction B, i.e. vertically to the actuation side 46 and towards the body (downwards in FIG. 2), the contact in the pedestal 44 is closed, as soon as the pressure point of the push button is exceeded.

Laterally, i.e. parallel to the body, the trigger 36 is completely surrounded by the trough-shaped protective element 38, which has a ring-shaped portion 48 and a bottom 50.

The ring-shaped portion 48 extends all around the trigger 36 so that the trigger 36 is arranged within the ring-shaped portion 48.

On the side facing the body, i.e. at the bottom in FIG. 2, the bottom 50 closes the ring-shaped portion 48 completely. In addition, the trigger 36 is attached to the bottom 50.

On the side facing away from the body, the tappet 42, more exactly the ring-shaped portion 48, has an actuating opening 52 which is parallel to the body surface when the article of clothing 10 is worn.

The height h of the protective element 38 from the side of the bottom 50 facing the body to the side of the ring-shaped portion 48 facing away from the body lies for example between 4 mm and 7 mm, in particular is about 6 mm.

In a top view, the protective element 38 and the actuating opening 52 have an elongated outer contour which corresponds to a rectangle with two attached semicircular segments and which has a longitudinal axis L that extends through the vertices of the semicircular segments. This shape can be seen in FIG. 3, in which the protective element 38 is indicated by broken lines.

For example the protective element 38 has a length I along the longitudinal axis L between 25 mm and 35 mm, in particular of about 31.5 mm, and a width b transversely to the longitudinal axis L between 15 mm and 26 mm, in particular of about 21 mm.

It is also conceivable, however, that the protective element 38 and the actuating opening 52 have another shape, such as an oval, rectangular or circular shape.

The protective element 38 is inserted into the cushioning unit 40. For this purpose, a protrusion 54 or a collar can be provided on the ring-shaped portion 48.

The cushioning unit 40 includes a receiving opening 56 into which the protective element 38 with the trigger 36 is inserted.

The receiving opening 56 has the same shape as the protective element 38 and is therefore also rectangular with attached semicircular segments in the illustrated embodiment.

In the illustrated embodiment, the circumference of the plate-like cushioning unit is also similar to the shape of the protective element 38 and hence also describes a rectangle with attached semicircular segments. Thus, the entire trigger device 28 has a longitudinal axis L.

However, any other shape of the outer circumference, such as rectangular, oval or circular shape, also is conceivable.

The cushioning unit 40 includes several layers, namely a layer 58 facing away from the body, a middle layer 60 and a layer 62 facing the body. In FIG. 2, the layer 58 facing away from the body is at the top and the layer 62 facing the body is at the bottom.

The layer 62 facing the body and the layer 58 facing away from the body can both be fixed to the middle layer 60.

The middle layer 60 is a padding layer which is made of a foamed material and is therefore soft and compressible to a certain extent.

The layer 58 facing away from the body and the layer 62 facing the body are top layers and impart stability to the padding layer of the middle layer 60, in particular for protection against pressure, abrasion and other environmental influences, such as heat. The layer 62 facing the body contains, for example, polyurethane and/or nylon. The layer 58 facing away from the body is made of solid cardboard or a thin plastic material, for example.

In the illustrated exemplary embodiment, the receiving opening 56 extends vertically through the entire cushioning unit 40, i.e. through all three layers 58, 60, 62.

It is also conceivable, however, that the receiving opening 56 only extends through parts of the cushioning unit 40. For example, the receiving opening 56 can end in the middle layer 60 so that it only extends through the layer 58 facing away from the body and through parts of the middle layer 60.

In the illustrated embodiment, the receiving opening 56 is formed off-center in the cushioning unit 40 so that the protective element 38 is also mounted off-center in the cushioning unit 40. The trigger 36 and the protective element 38 may be arranged closer to the thumb or the cutout 14 for the thumb.

The pressure plate 64 of the trigger 36 substantially has the shape of the actuating opening 52, hence, in this embodiment it is also rectangular with attached semicircular segments.

The pressure plate 64 is arranged in the actuating opening 52 at least partly and resiliently mounted with respect to the protective element 38.

In the illustrated embodiment, the pressure plate 64 is resiliently connected with the layer 58 of the cushioning unit 40 facing away from the body via webs 66. More exactly, the pressure plate 64 is formed integrally with the webs 66 and the layer 58 facing away from the body, i.e. the top layer.

It is also conceivable that the pressure plate 64 is attached to the ring-shaped portion 48 of the protective element 38 or formed integrally with the same.

It is furthermore conceivable that the pressure plate 64 is connected, for example adhesively bonded, with the cover 34.

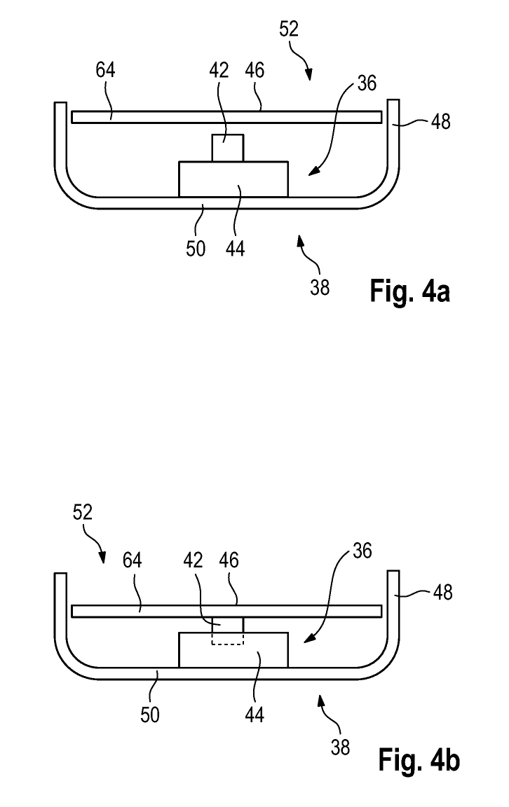

In FIGS. 4a and 4b the protective element 38 with the trigger 36 and the pressure plate 64 is shown in greatly simplified form, in order to illustrate the function of the trigger device 28. In particular, the size ratios and paths are not true to scale for clarification.

FIG. 4a shows the electrically non-connected starting position of the trigger device 28, in particular of the trigger 36, and FIG. 4b shows the trigger position upon reaching the pressure point.

In the starting position, the tappet 42 distinctly protrudes from the pedestal 44 of the trigger 36. In this position, the pressure plate 64 can be spaced from the tappet 42 and may also be outside the space defined by the protective element 38 so that the actuation side 46 facing away from the body is at its highest point, i.e. is furthest away from the body of the user.

In the illustrated embodiment, the ring-shaped portion 48 of the protective element 38 in this starting position protrudes beyond the actuation side 46 facing away from the body. Hence, the trigger 36 lies completely in the region surrounded by the protective element 38.

It is, however, also conceivable that in the starting position the actuation side 46 facing away from the body protrudes beyond the protective element 38.

When the trigger device 28 now is actuated, i.e. a force is exerted on the pressure plate 64 in actuating direction B, namely a force in axial direction of the ring-shaped portion 48 towards the body, the pressure plate 64 is moved partly or entirely into the ring-shaped portion 48. It initially gets in contact with the tappet 42 of the trigger 36 and then moves the tappet 42 further into the pedestal 44.

During this movement, a pressure point of the trigger 36 is reached, upon exceedance of which the trigger 36 responds, i.e. in this case the contact or the switch is closed. Upon reaching this pressure point, the trigger 36 or the actuation side 46 of the pressure plate 64 facing away from the body is in its trigger position.

In its trigger position, which is shown in FIG. 4b, the ring-shaped portion 48 protrudes in the illustrated side view beyond the actuation side 46 facing away from the body. In other words, the protective element 38, as seen from the body, is further away in the trigger position than the actuation side 46 facing away from the body.

The pressure plate 64 may also be omitted, so that the actuation side 46 facing away from the body is then formed by the end of the tappet 42 facing away from the body. In the trigger position, the tappet 42 then completely lies in the space enclosed by the protective element 38.

In each of FIGS. 5a to 5c, the article of clothing 10 or the glove 11 is shown in the condition worn on the hand.

The various gloves 11 are work gloves, wherein in FIGS. 5a to 5c gloves 11 of different sizes are shown.

The size shown in FIG. 5a is a small size, for example size S. In FIG. 5b a medium size, for example size M, is shown and in FIG. 5c a large size, for example size L, is shown.

The gloves 11 of different sizes form a glove set 68 and may all have an identical trigger device 28. The trigger device 28 lies in the area of the hand surfaces of the user and in particular can be arranged between the ball of the thumb and the metacarpophalangeal joints of the middle and ring fingers.

The trigger devices 28 however are oriented differently in dependence on the size of the glove 11. This can be achieved by different sizes of the angle α.

The angle α is different for the different sizes of the work glove, wherein the angle α becomes larger with decreasing size of the glove 11. The dependence of the angle α on the size of the glove 11 hence is inversely proportional.

In a small glove 11 (FIG. 5a) the angle for example is between 30° and 50°, in particular about 40°.

In a glove 11 of medium size (FIG. 5b) the angle is, for example, between 15° and 35°, in particular about 25°, and in a large glove 11 (FIG. 5c) the angle is between 0° and 20°, in particular about 10°.

In this way it is ensured that the trigger device 28 can be worn ergonomically.

To activate the trigger 36, the user bends his/her middle finger, ring finger, index finger and/or small finger and presses on the pressure plate 64 with the finger tips. The pressure plate is moved into the ring-shaped portion 48 and activates the trigger 36 (cf. FIG. 4).

Due to the pressure plate 64, the user can press onto any point of the actuating opening 52 with his/her finger, in order to activate the trigger 36. The user therefore does not need to hit the tappet 42 of the trigger 36, which is much smaller than the pressure plate 64.

For manufacturing a glove 11, in particular the illustrated work gloves, the tape-shaped base body 12 is provided initially, on which neither the trigger device 28 nor the holder 20 are mounted. Possibly, the first and second fastening elements 24 and 26 already are attached to the base body 12.

In a next step, the trigger device 28 and the holder 20 are then arranged on the same side A_{ab} of the base body 12 facing away from the body.

Then, the cover 34 is placed on the trigger device 28.

In case the first and second fastening elements 24, 26 are not attached to the base body 12 already, the same are also arranged at their respective positions on the base body 12.

An adhesive, for example a thermally activatable adhesive, may be applied on the holder 20, the cover 34 and possibly on the fastening elements 24, 26 and possibly the trigger device 28.

Subsequently, the base body 12 with the components arranged thereon is heated and connected by pressing.

The press by means of which the components are heated and connected may comprise on a recess for the holder 20 one of its jaws and on the other jaw a recess for the trigger device 28 or the elevation 32.

While pressing, the base body 12 is deformed by the trigger device 28 such that the trigger device and the base body 12 protrude from the remaining base body 12 in the region of the trigger device 28. At the same time, the heat necessary for activating the adhesive is supplied by the press so that the holder 20 and the cover 34 are attached to the base body 12, for example in that the applied hot-melt adhesive melts.

After pressing, the cover 34 forms one surface together with the remaining base body 12, which faces away from the body.

Thus, the trigger device 28 and the holder 20 can be attached to the base body 12 in the same working step.

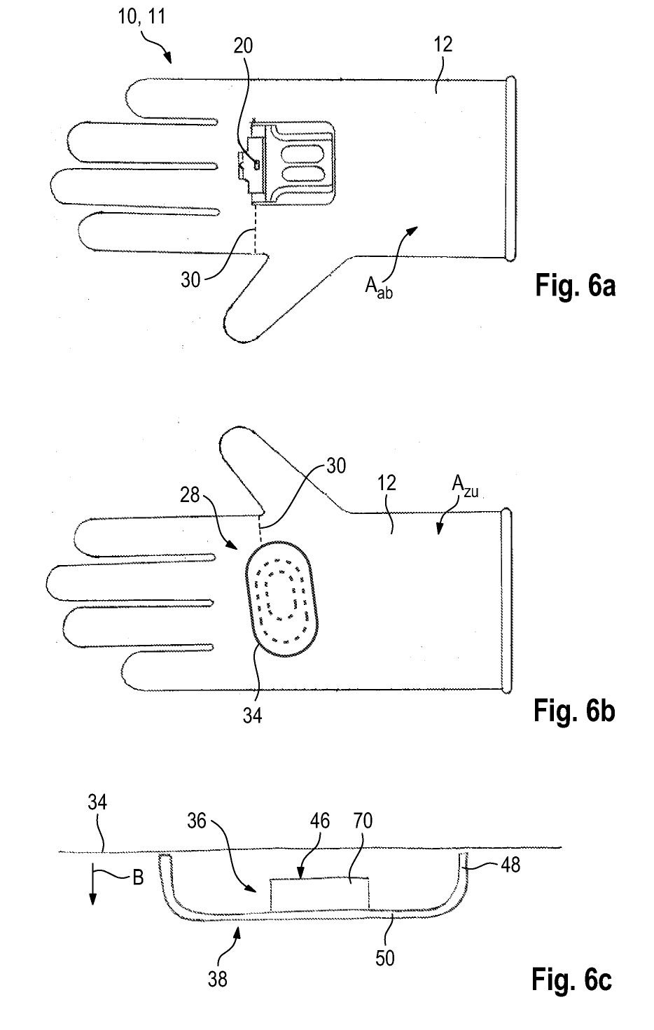

FIGS. 6a and 6b show a second embodiment of an article of clothing 10, which in essence corresponds to the first embodiment. Correspondingly, only the differences will be discussed in the following, and identical and functionally equivalent parts are provided with the same reference numerals.

The article of clothing of the second embodiment is also a glove 11.

The glove 11 of the second embodiment however is a full glove, i.e. the base body 12 has individual fingers.

In this embodiment, too, the base body 12 has a hand surface portion 16 on which the trigger device 28 is provided, and a hand back portion 18 on which the holder 20 for an electronic module is provided.

As can be seen in FIG. 6c, the trigger 36 of the trigger device 28 of the second embodiment differs from that of the first embodiment.

In the second embodiment, the trigger 36 is a touch-sensitive surface 70 and designed without pressure plate. The touch-sensitive surface 70 for example is a capacitive or resistive touch-sensitive surface.

The actuating direction B is vertical to the touch-sensitive surface 70.

The actuation side 46 of the trigger 36 facing away from the body in this case is the touch-sensitive surface 70 itself, which however is designed immovable.

Correspondingly, the touch-sensitive surface 70 or the actuation side 46 of the trigger 36 facing away from the body is at the same position both in the starting position and in the trigger position.

The ring-shaped portion 48 of the protective element 38 thus extends from the body beyond the touch-sensitive surface 70.

In addition, no pressure plate is provided in this second embodiment.

Of course, the individual features of the two embodiments can be combined with each other in any way. In particular, the trigger 36 of the first embodiment also can be a touch-sensitive surface 70.

1. An article of clothing to be worn on the body, with a trigger device, wherein the trigger device comprises an electric trigger which has an actuation side facing away from the body, and a rigid protective element for the trigger, which laterally surrounds the trigger at least partly, wherein in a side view of the trigger device the protective element extends at least up to the actuation side of the trigger in its trigger position facing away from the body.

2. The article of clothing according to claim 1, wherein the trigger has at least one of a push button and a touch-sensitive surface.

3. The article of clothing according to claim 2, wherein in the non-actuated starting position the actuation side of the trigger facing away from the body at least one of does not protrude beyond the protective element and completely lies in the area surrounded by the protective element.

4. The article of clothing according to claim 1, wherein the trigger device includes a cushioning unit which surrounds the protective element laterally and/or on its side facing the body at least partly.

5. The article of clothing according to claim 4, wherein the cushioning unit includes a padding layer and at least one top layer.

6. The article of clothing according to claim 1, wherein the protective element has a closed ring-shaped portion, wherein the trigger is arranged within the ring-shaped portion.

7. The article of clothing according to claim 6, wherein the protective element includes a bottom which at least for the most part closes the ring-shaped portion on the side facing the body and on which the trigger is mounted.

8. The article of clothing according to claim 1, wherein on its side facing away from the body the protective element has an actuating opening.

9. The article of clothing according to claim 8, wherein the trigger comprises a pressure plate which forms the actuation side facing away from the body, which has the shape of the actuating opening and which is arranged at least partly in the actuating opening, wherein the pressure plate is resiliently mounted with respect to the protective element.

10. The article of clothing according to claim 1, wherein at least one of the protective element and the trigger and the protective element, the trigger and the cushioning unit are a pre-assembled unit.

11. The article of clothing according to claim 1, wherein the article of clothing is a glove with a hand surface portion covering the hand surface, wherein the trigger device is arranged on the hand surface portion.

12. The article of clothing according to claim 11, wherein the glove includes a holder for an electronic module, wherein the holder has at least one electrical contact element which is electrically connected with the trigger.

13. The article of clothing according to claim 11, wherein the glove has a tape-shaped base body in which a cutout for a thumb is formed.

14. A method for manufacturing a glove, comprising the following steps:
a) providing a band-shaped base body,
b) placing the trigger device on the side of the base body facing away from the body, and
c) heating and connecting the base body to the trigger device,
wherein after connecting the trigger device at least partly protrudes from the remaining base body on the side facing the body.

15. The method according to claim 14, wherein before connecting a cover is arranged on the trigger device, which after connecting forms one surface with the remaining base body, which faces away from the body.

16. The method according to claim 14, wherein before connecting a holder for an electronic module is placed on the same side of the base body as the trigger device, wherein after connecting the holder is arranged on the side of the base body facing away from the body.

17. A glove set with at least two gloves of different size, which have a hand surface portion of different size covering the hand surface, and with a trigger device on each glove, wherein the trigger devices for the differently large gloves are of elongated shape, and wherein with increasingly smaller gloves the trigger device with its longitudinal axis is arranged at an increasingly larger angle to the transverse direction of the hand surface portion.

18. The glove set according to claim 17, wherein at least two of the trigger devices of the at least two gloves of different size are equally large.

19. The article of clothing according to claim 1, wherein the article of clothing is a work glove.

20. The article of clothing according to claim 11, wherein the trigger device is arranged in the area of the hand surface portion which in proper use of the glove lies between the ball of the thumb and the metacarpophalangeal joints of the middle and ring fingers.
